(19) United States
(12) Patent Application Publication
(10) Pub. No.: US 2025/0254916 A1
(43) Pub. Date: Aug. 7, 2025

(54) SEMICONDUCTOR STRUCTURE INCLUDING INTERMEDIATE CONDUCTIVE LAYERS AND METHOD FOR MANUFACTURING THE SAME

(71) Applicant: TAIWAN SEMICONDUCTOR MANUFACTURING COMPANY, LTD., Hsinchu (TW)

(72) Inventors: Yen-Chieh HUANG, Hsinchu (TW); Huai-Ying HUANG, Hsinchu (TW); Yu-Chuan SHIH, Hsinchu (TW); Chun-Chieh LU, Hsinchu (TW); I-Che LEE, Hsinchu (TW); Yu-Ming LIN, Hsinchu (TW)

(73) Assignee: TAIWAN SEMICONDUCTOR MANUFACTURING COMPANY, LTD., Hsinchu (TW)

(21) Appl. No.: 18/435,378

(22) Filed: Feb. 7, 2024

(51) Int. Cl. H01L 29/417; H01L 29/40; H01L 29/786

(52) U.S. Cl. CPC H10D 30/6729; H10D 30/6755; H10D 64/01

(57) ABSTRACT

A method for manufacturing a semiconductor device includes: forming a channel including a semiconductor material; forming two intermediate conductive layers in contact with the channel and spaced apart from each other; and forming two conductive contacts respectively on the two intermediate conductive layers. Each of the intermediate conductive layers includes at least one stacking unit. The at least one stacking unit includes two first metal oxide layers spaced apart from each other and a second metal oxide layer disposed between the two first metal oxide layers and extending along a lengthwise line such that the two first metal oxide layers are opposite to each other relative to the lengthwise line. Each of the first metal oxide layers includes first metal atoms. The second metal oxide layer includes second metal atoms that are different from the first metal atoms.

### BACKGROUND

Thin film transistors, which are manufactured using thin film techniques, are known to be used in various applications. The thin film transistors may be formed in a front-end-of-line process, or may be embedded in a back-end-of-line interconnect structure, thereby saving chip area of an integrated circuit.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic sectional view illustrating a semiconductor structure in accordance with some embodiments.

FIG. 2 is a schematic sectional view illustrating a portion of each intermediate conductive layer having one stacking unit in accordance with some embodiments.

FIG. 3 is a schematic sectional view illustrating a portion of each intermediate conductive layer having one stacking unit in accordance with some other embodiments.

FIG. 4 is a schematic view illustrating a portion of each intermediate conductive layer having multiple stacking units in accordance with some embodiments.

FIG. 5 is a schematic view illustrating a portion of each intermediate conductive layer having multiple stacking units in accordance with some other embodiments.

FIG. 6 is a flow diagram illustrating a method for manufacturing a semiconductor structure in accordance with some embodiments.

FIGS. 7 to 12 illustrate schematic views of intermediate stages of the method depicted in FIG. 6 in accordance with some embodiments.

FIG. 13 is a graph illustrating a flow rate versus time for an oxygen-containing precursor gas, a first metal precursor gas, a second metal precursor gas, and a third metal precursor gas used for forming a preformed stack which has a configuration similar to that of the intermediate conductive layer shown in FIG. 5 in accordance with some embodiments.

FIG. 14 is a graph similar to FIG. 13, but illustrating a modified process for forming the preformed stack which has a configuration similar to that of the intermediate conductive layer shown in FIG. 5 in accordance with some other embodiments.

FIG. 15 is a graph illustrating a flow rate versus time for the oxygen-containing precursor gas, the first metal precursor gas, and the second metal precursor gas used for forming a preformed stack which has a configuration similar to that of the intermediate conductive layer shown in FIG. 4 in accordance with some embodiments.

FIG. 16 is a graph similar to FIG. 15, but illustrating a modified process for forming the preformed stack which has a configuration similar to that of the intermediate conductive layer shown in FIG. 4 in accordance with some other embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the terms “about” and “substantially” even if the terms “about” and “substantially” are not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the terms “about” and “substantially,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

Metal oxide (e.g., indium gallium zinc oxide, IGZO) is widely used as a channel material of a thin film transistor. When two source/drain metal contacts are in direct contact with the metal oxide channel, metal atoms (e.g., tungsten, aluminum, etc.) in each of the two source/drain metal contacts are likely to diffuse into a surface region of the metal oxide channel. As such, an interfacial metal oxide, which has a relatively high electrical resistance and which includes the metal atoms from the source/drain metal contacts and oxygen atoms from the metal oxide channel, may be formed at an interface between the metal oxide channel and a respective one of the two source/drain metal contacts, thereby undesirably increasing a contact resistance between the metal oxide channel and the respective source/drain metal contact. In order to prevent formation of the interfacial metal oxide, embodiments of the present disclosure provides a semiconductor device, in which two intermediate conductive layers are each formed between the metal oxide channel and the respective source/drain metal contact. Furthermore, since the intermediate conductive layers are formed by an oxygen-rich process, less oxygen vacancies are present in the intermediate conductive layers. Hence, the metal atoms in the source/drain contacts are less likely to diffuse into or react with the intermediate conductive layers. In addition, each of the two intermediate conductive layers is configured as a multi-layered structure and is configured to have a predetermined symmetry, thereby having a greatly reduced electrical resistance.

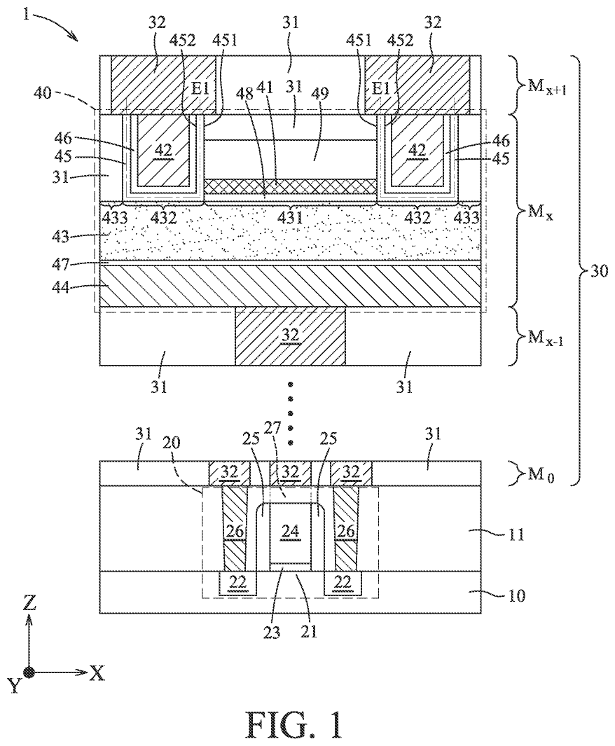

FIG. 1 is a schematic sectional view illustrating a semiconductor structure 1 in accordance with some embodiments. The semiconductor structure 1 includes a substrate 10, a first semiconductor device 20 (which serves as a front-end-of-line (FEOL) transistor), an inter-layer dielectric (ILD) layer 11 formed on the substrate 10 to cover the first semiconductor device 10, an interconnect structure 30 formed on the ILD layer 11, and a second semiconductor device 40 (which serves as a back-end-of-line (BEOL) transistor) formed in the interconnect structure 30. It is noted that the second semiconductor device 40 is not limited to be located directly above the first semiconductor device 20. In some other embodiments, the first semiconductor device 20 shown in FIG. 1 may be omitted. In such case, the second semiconductor device 40 may be directly formed on the substrate 10, or formed on a buffer layer (not shown) that is performed on the substrate 10 and that is used for improving the film quality of a film to be formed thereon.

In some embodiments, the substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 10 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 10 may be configured as a semiconductor-on-insulator substrate. In some embodiments, the semiconductor material in the substrate 10 may be un-doped, or may be doped with impurities (e.g., n-type impurities or p-type impurities) to form a well portion for the first semiconductor device 20. In some yet other embodiments, the substrate 10 may be a glass substrate. Other suitable materials and configurations for the substrate 10 are within the contemplated scope of the present disclosure.

In some embodiments, the first semiconductor device 20 may be a field-effect transistor (FET), and includes a channel 21, two source/drain portions 22 formed at two opposite sides of the channel 21, a gate dielectric layer 23 formed on the channel 21, a gate electrode 24 formed on the gate dielectric layer 23 such that the channel 21 is spaced apart from the gate electrode 24 by the gate dielectric layer 23, and two dielectric spacers 25 formed at two opposite sides of the gate electrode 24. In some embodiments, the first semiconductor device 20 further includes two source/drain contacts 26 and a gate contact 27 formed in the ILD layer 11 and spaced apart from each other. The source/drain contacts 26 are respectively formed on the source/drain portions 22, and the gate contact 27 is formed on the gate electrode 24. In some embodiments, as shown in FIG. 1, the first semiconductor device 20 may be configured as a planar FET, in which (i) the source/drain portions 22 are formed in the substrate 10 by an implantation process, and (ii) a portion of the substrate 10, which is located between the source/drain portions 22, serves as the channel 21. The source/drain portions 22 may be doped with impurities to have an n-type conductivity or a p-type conductivity according to the type of the first semiconductor device 20 (i.e., the source/drain portions 22 have the n-type conductivity when the first semiconductor device 20 is an n-FET; and the source/drain portions 22 have the p-type conductivity when the first semiconductor device 20 is a p-FET). In some embodiments, the gate dielectric layer 23 may be made of silicon oxide, and the gate electrode 24 may be made of polycrystalline silicon. In some other embodiments not shown herein, the first semiconductor device 20 may be configured as a fin-type field-effect transistor (FinFET), or a gate-all-around field-effect transistor (GAAFET). In such case, the gate dielectric layer 23 may include a high dielectric constant (high-k) material, and the gate electrode 24 include a metallic material. Other three-dimensional (3D) transistor structures suitable for the first semiconductor device 20 are within the contemplated scope of the present disclosure.

In some embodiments, the ILD layer 11 includes a dielectric material. In some embodiments, the dielectric material for forming the ILD layer 11 may have a low dielectric constant, and may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOxCy), spin-on-glass (SOG), or combinations thereof. Other dielectric materials suitable for the ILD layer 11 are within the contemplated scope of the present disclosure. The interconnect structure 30 includes a plurality of interconnect layers which are sequentially formed on the ILD layer 11. Four of the interconnect layers are exemplarily shown in FIG. 1, and are respectively represented by M₀, Mₓ₋₁, Mₓ, Mₓ₊₁, where x is an integer not less than 2. Other interconnect layers between the interconnect layers M0 and Mx−1 are omitted. Each of the interconnect layers M₀, . . . . Mₓ₋₁, Mₓ, Mₓ₊₁ includes an inter-metal dielectric (IMD) portion 31, and a plurality of electrically conductive elements 32 (for example, metal contacts, metal lines, and/or metal vias) formed in the IMD portion 31. Each of the electrically conductive elements 32 in each of the interconnect layers M₀, . . . . Mₓ₋₁, Mₓ, Mₓ₊₁ is connected to a corresponding one of the electrically conductive elements 32 in an adjacent one of the interconnect layers M₀, . . . . Mₓ₋₁, Mₓ, Mₓ₊₁. In some embodiments, the second semiconductor device 30 is formed in the IMD portion 31 of the interconnect layer Mₓ. In some embodiments, the electrically conductive elements 32 may include a low resistance electrically conductive material such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), golden (Au), silver (Ag), aluminum (Al), osmium (Os), alloys thereof, or combinations thereof. Possible low dielectric constant (low-k) materials suitable for the IMD portion 31 are similar to those for forming the ILD layer 11, and thus the details thereof are omitted for the sake of brevity.

In some embodiments, the second semiconductor device 40 may be a thin-film transistor (TFT), and includes a channel 41 that includes a semiconductor material, two conductive contacts 42 formed on the channel 41 and spaced apart from each other, a gate dielectric layer 43 formed on the channel 41, a gate electrode 44 formed on the gate dielectric layer 43 such that the channel 41 is separated from the gate electrode 44 by the gate dielectric layer 43, and two intermediate conductive layers 45, each of which is formed between the channel 41 and a respective one of the conductive contacts 42 so as to prevent an interfacial metal oxide from being formed between the channel 41 and each of the conductive contacts 42. In some embodiments, as shown in FIG. 1, the gate electrode 44 is located beneath the channel 41 such that the gate electrode 44 and the channel 41 are respectively located proximate to and distal from the substrate 10. In such case, the second semiconductor device 40 is referred to as a bottom-gate TFT, but is not limited thereto. In some other embodiments not shown herein, the second semiconductor device 40 may be configured as a top-gate TFT, a double-gate TFT, a vertical TFT, or 3-dimensional TFT. For the top-gate TFT, the gate electrode and the channel are respectively located distal from and proximate to the substrate. The double gate TFT includes a lower gate electrode and an upper gate electrode which are respectively separated from the channel by a lower gate electric layer and an upper gate dielectric layer. The lower and upper gate electrodes are disposed at two opposite sides of the channel, and are respectively located proximate to and distal from the substrate. Other configurations using the intermediate conductive layers are within the contemplated scope of the present disclosure. In some embodiments, the second semiconductor device 40 may be applied to static random-access memory (SRAM), dynamic random-access memory (DRAM, e.g., one-transistor/one-capacitor (1T-1C) DRAM cell, 3-dimensional DRAM structure, standalone DRAM structure, embedded DRAM structure, etc.), ferroelectric memories (e.g., 1T-1C ferroelectric random-access memory memory (1T-1C FeRAM), 1T FeRAM, metal-ferroelectric-metal field-effect transistor-based (MFMFET-based) FeRAM, metal-ferroelectric-metal-insulator-semiconductor field-effect transistor-based (MFMISFET) FeRAM, etc.), or peripheral devices (e.g., power gates, input/output (I/O) devices, or selectors for memory cells, etc.). It is noted that the second semiconductor device 40 is not limited to be formed in the IMD portion 31 of the interconnect layer Mₓ. In some embodiments not shown herein, the second semiconductor device 40 may be formed in any one of the interconnect layers M₀, . . . . Mₓ₋₁, Mₓ₊₁.

In some embodiments, as shown in FIG. 1, the gate electrode 44 is formed on the IMD portion 31 of the interconnect layer Mₓ₋₁, and is connected to one of the electrically conductive elements 32 of the interconnect layer Mₓ₋₁. In some embodiments, the gate electrode 44 includes tungsten (W), platinum (Pt), aluminum (Al), silver (Ag), copper (Cu), nickel (Ni), or alloys thereof. Other metallic material suitable for forming the gate electrode 44 are within the contemplated scope of the present disclosure.

In some embodiments, the gate dielectric layer 43 is formed on the gate electrode 44 (in other words, the gate electrode 44 is formed on a lower surface of the gate dielectric layer 43). In some embodiments, the gate dielectric layer 43 may include silicon oxide, silicon nitride, silicon oxynitride, or a high-k dielectric material (such as hafnium oxide, hafnium tantalum oxide, zirconium oxide, zirconium aluminum oxide, hafnium aluminum oxide, hafnium silicon oxide, aluminum oxide, etc.). In some other embodiments, when the second semiconductor device 40 is formed as a FeRAM, the gate dielectric layer 43 may include a ferroelectric material (such as hafnium zirconium oxide (HZO), barium titanate (BaTiO₃), lead titanate, lead zirconate, lithium niobate, sodium niobate, potassium niobate, potassium tantalite, bismuth scandate, bismuth ferrite, aluminum scandium nitride, or hafnium oxide doped with yttrium (Y), lanthanum (La), gadolinium (Gd), erbium (Er), titanium (Ti), zirconium (Zr), aluminum (Al), or tantalum (Ta)). Other suitable materials for the gate dielectric layer 43 are within the contemplated scope of disclosure. In some embodiments, the gate dielectric layer 43 has a thickness ranging from about 1 nm to about 500 nm. In some embodiments, as shown in FIG. 1, the gate dielectric layer 43 has a first region 431 for forming the channel 41 thereon, two second regions 432 respectively for landing the two conductive contacts 42 thereon, and a third region 433 for being covered by the IMD portion 31 of the interconnect layer Mₓ. The regions 431, 432, 433 are displaced from each other.

In some embodiments, the channel 41 is formed on the first portion 431 of the gate dielectric layer 43 (in other words, the gate dielectric layer 43 is formed on a lower surface of the channel 41). In some embodiments, the semiconductor material for forming the channel 41 includes silicon (Si), germanium (Ge), silicon germanium, silicon germanium carbide, gallium arsenic, indium phosphide, gallium phosphide, gallium nitride, gallium antimony, aluminum arsenic, indium arsenic, indium antimony, aluminum gallium arsenic, gallium indium arsenic, gallium indium phosphide, indium aluminum arsenic, aluminum indium gallium phosphide, cadmium sulfide, cadmium selenide, zinc sulfide, zinc selenide, zinc telluride, lead sulfide, lead telluride, mercury telluride, or combinations thereof. In some other embodiments, the semiconductor material for forming the channel 41 may be a metal oxide semiconductor, such as indium gallium zinc oxide (IGZO), indium zinc oxide (IZO), indium gallium tin oxide (IGSnO), indium gallium tin zinc oxide (IGSnZnO), which has extra carriers (i.e., electrons) capable of moving in the channel 41 during operation of the second semiconductor device 40. Therefore, the second semiconductor device 40 using such metal oxide semiconductor as the channel 41 is referred to as an n-type thin-film transistor. In some embodiments, when the channel 41 is made of IGZO, such IGZO may be represented by a chemical formula of (Ga₂)ₓ₁(In₂)₍₁₋ₓ₁₎Zn_{y1}O₇, where x1 ranges from about 0.2 to about 0.75, and y1 is greater than zero and not greater than about 0.75. In some embodiments, the channel 41 may have a thickness ranging from about 1 nm to about 100 nm.

In some embodiments, the conductive contacts 42 are respectively landed on the second regions 432 of the gate dielectric layer 43, and are respectively located at two opposite sides of the channel 41 (in other words, each of the conductive contacts 42 is disposed on one of two side surfaces of the channel 41). When the second semiconductor device 40 is formed as a FeRAM and includes the conductive contacts 42 having such arrangement as described above, a polarizable region of the gate dielectric layer can be enlarged. Accordingly, a memory window of the FeRAM may be enlarged. In some embodiments, the conductive contacts 42 may be referred to as a source contact and a drain contact, respectively. In some embodiments, the conductive contacts 42 may include tungsten (W), platinum (Pt), aluminum (Al), cobalt (Co), copper (Cu), titanium (Ti), tantalum (Ta), zirconium (Zr), hafnium (Hf), or alloys thereof. Other metallic materials suitable for forming the conductive contacts 42 are within the contemplated scope of the present disclosure. In some embodiments, each of the conductive contacts 42 has an upper surface distal from the substrate 10, a lower surface proximate to the surface 10, and an interconnecting surface connecting the upper surface and the lower surface.

In some embodiments, the intermediate conductive layers 45 are respectively formed around the conductive contacts 42 such that the lower surface and the interconnecting surface of each of the conductive contacts 42 are covered by a respective one of the intermediate conductive layers 45. In such case, not only the channel 41 is separated from each of the conductive contacts 42 by a respective one of the intermediate conductive layers 45, but also the gate dielectric layer 43 is separated from each of the conductive contacts 42 by a respective one of the intermediate conductive layers 45. In some embodiments, each of the intermediate conductive layers 45 includes at least two different metal oxides. In some embodiments, the metal oxides for forming the intermediate conductive layers 45 may include first metal atoms and second metal atoms. In some other embodiments, the metal oxides for forming of the intermediate conductive layers 45 may include three different metal oxides (i.e., the metal oxides includes the first metal atoms, the second metal atoms and third metal atoms). The first, second and third metal atoms are different from each other. Each of the first, second and third metal atoms may be selected from indium (In), gallium (Ga), zinc (Zn), and tin (Sn). For example, each of the intermediate conductive layers 45 may be made of indium gallium zinc oxide (IGZO), indium gallium oxide (IGO), indium zinc oxide (IZO), zinc tin oxide (ZnSnO, ZTO), gallium zinc oxide (GZO), indium tin oxide (InSnO, ITO), or other high conductive metal oxides having high donor density (Na). In some embodiments, the donor density is n-type donor density. In comparison with the metal oxide semiconductor for forming the channel 41 (such as the examples described in the previous paragraph), the metal oxides for forming the intermediate conductive layers 45 has a relatively high donor (i.e., electrons) density. In other words, the conductivity of the metal oxides for forming the intermediate conductive layers 45 is greater than the metal oxide semiconductor for forming the channel 41. The conductivity of the intermediate conductive layers 45 may be controlled by the atomic composition thereof. For example, in some embodiments, when the intermediate conductive layers 45 is made of IGZO, such IGZO may be represented by a chemical formula of (Ga₂)ₓ₂(In₂)₍₁₋ₓ₂₎Zn_{y2}O₇, where x2 is greater than zero and less than about 0.5, and y2 is greater than zero and not greater than about 1. In some embodiments, each of the intermediate conductive layers 45 has a thickness ranging from about 5 nm to about 500 nm.

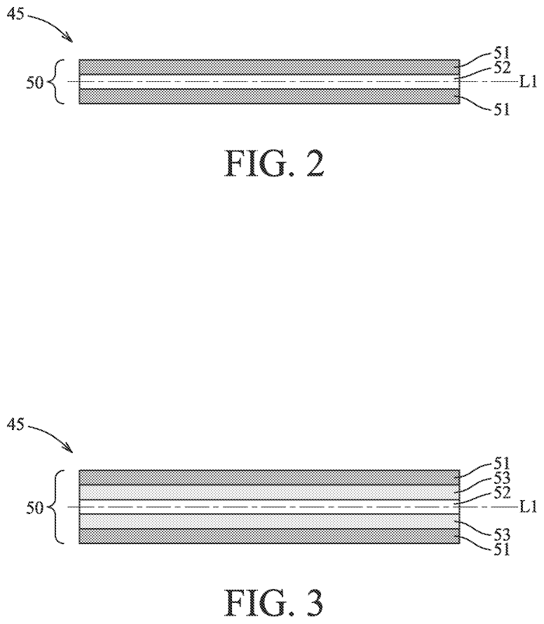

As shown in FIG. 1, each of the intermediate conductive layers 45 has a first surface 451 and a second surface 452 opposite to the first surface 451, and extends along a reference plane E1 which is equally spaced apart from the first surface 451 and the second surface 452. Each of the intermediate conductive layers 45 may include one or multiple stacking units 50. FIG. 2 is a schematic sectional view illustrating a portion of each intermediate conductive layer 45 including one stacking unit 50 in accordance with some embodiments. The stacking unit 50 includes two first metal oxide layers 51 each including the first metal atoms, and a second metal oxide layer 52 including the second metal atoms. The two first metal oxide layers 51 have the same thickness, and are spaced apart from each other, and the second metal oxide layer 52 is disposed between the two first metal oxide layers 51. The second metal oxide layer 52 extends along a lengthwise line L1 such that the first metal oxide layers 51 are opposite to each other relative to the lengthwise line L1. In some embodiments, the first metal oxide layers 51 are symmetric with each other relative to the lengthwise line L1. In some embodiments, a donor density in each of the first metal oxide layers 51 is greater than a donor density in the second metal oxide layer 52. Based on the required composition for the intermediate conductive layers 45, the first and second metal atoms (and third metal atoms to be described in the following paragraph) are each selected from, for example, but not limited to, indium (In), gallium (Ga), zinc (Zn), and tin (Sn). In view of the fact that each of indium oxide, zinc oxide and tin oxide has a donor density that is greater than a donor density of gallium oxide, in the case that each of the intermediate conductive layers 45 is made of indium gallium oxide (IGO), in the stacking unit 50, each of the first metal oxide layers 51 is formed as an indium oxide layer, and the second metal oxide layer 52 is formed as a gallium oxide layer. In other words, in such case, the first metal atoms are indium, and the second metal atoms are gallium. In the case that each of the intermediate conductive layers 45 is made of gallium zinc oxide (GZO), in the stacking unit 50, each of the first metal oxide layers 51 is formed as a zinc oxide layer, and the second metal oxide layer 52 is formed as a gallium oxide layer. In other words, in such case, the first metal atoms are zinc, and the second metal atoms are gallium. In the case that each of the intermediate conductive layers 45 is made of indium zinc oxide (IZO), zinc tin oxide (ZnSnO, ZTO) or indium tin oxide (InSnO, ITO), since all of indium oxide, zinc oxide and tin oxide have a relatively high donor density, each of the first and second metal oxide layers 51, 52 may be formed as an indium oxide layer, a zinc oxide layer or a tin oxide layer, and the metal oxide of the first metal oxide layers 51 is different from the metal oxide of the second metal oxide layer 52. In other words, in such case, each of the first and second metal atoms may be selected from indium, zinc and tin, and the first and second metal atoms are different from each other.

FIG. 3 is a schematic sectional view illustrating a portion of each intermediate conductive layer 45 including one stacking unit 50 in accordance with some other embodiments. The stacking unit 50 shown in FIG. 3 has a configuration similar to that of the stacking unit 50 shown in FIG. 2, except that the stacking unit 50 shown in FIG. 3 further includes two third metal oxide layers 53 each including the third metal atoms. The two third metal oxide layers 53 have the same thickness. Each of the third metal oxide layers 53 is formed between the second metal oxide layer 52 and a respective one of the two first metal oxide layers 51 such that the two third metal oxide layers 53 are opposite to each other relative to the lengthwise line L1. In some embodiments, the two third metal oxide layers 53 are symmetric with each other relative to the lengthwise line L1. In some embodiments, a donor density in each of the third metal oxide layers 53 is greater than a donor density in the second metal oxide layer 52. In the case that each of the intermediate conductive layers 45 is made of indium gallium zinc oxide (IGZO), in the stacking unit 50, each of the first metal oxide layers 51 is formed as an indium oxide layer, the second metal oxide layer 52 is formed as a gallium oxide layer, and each of the third metal oxide layers 53 is formed as a zinc oxide layer. Alternatively, each of the first metal oxide layers 51 is formed as a zinc oxide layer, the second metal oxide layer 52 is formed as a gallium oxide layer, and each of the third metal oxide layers 53 is formed as an indium oxide layer. In other words, in such case, each of the first and third metal atoms can be selected from indium and zinc, the first and third metal atoms are different from each other, and the second metal atoms are gallium.

In the case that each of the intermediate conductive layers 45 includes a single stacking unit 50 (see FIG. 2 or 3), the lengthwise line L1 shown in FIG. 2 or FIG. 3 is located within the reference plane E1 shown in FIG. 1.

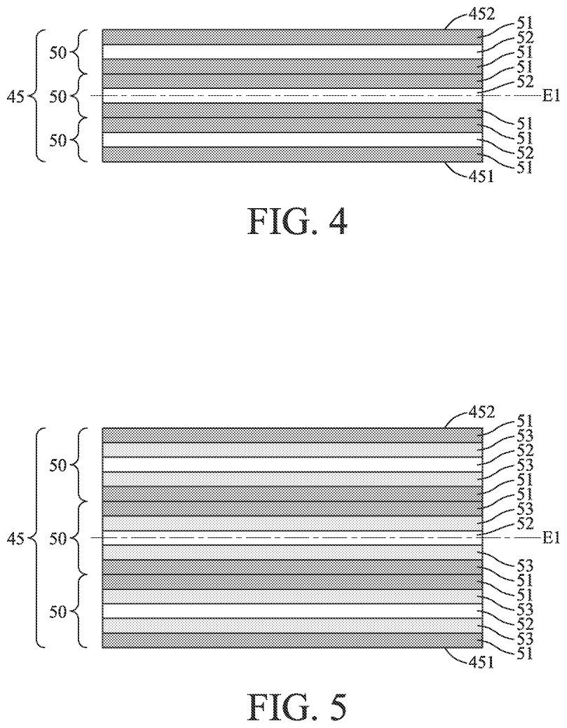

FIG. 4 is a schematic view illustrating a portion of each intermediate conductive layer 45 including multiple stacking units 50 in accordance with some embodiments, where each stacking unit 50 has a configuration as shown in FIG. 2. FIG. 5 is a schematic view similar to FIG. 4, but each stacking unit 50 has a configuration as shown in FIG. 3. It is noted that the number of the stacking units 50 shown in FIGS. 4 and 5 is three, but is not limited thereto. In practice, the number of the stacking units 50 may vary according to the thickness of each of the intermediate conductive layers 45.

The stacking units 50 in each of the intermediate conductive layers 45 are arranged such that at least a portion of each of the two intermediate conductive layers 45 is divided by the reference plane E1 into two halves which are mirror symmetric to each other. In some embodiments, as shown in FIG. 1, each of the intermediate conductive layers 45 has a horizontal portion, two vertical portions located at two opposite sides of the horizontal portion, and two corner portions each interconnecting the horizontal portion and a respective one of the vertical portions. The horizontal portion and each of the two vertical portions, are each divided by the reference plane E1, resulting in two halves of the horizontal portion being mirror symmetric to each other, and two halves of each of the two vertical portions being mirror symmetric to each other. Owing to the symmetry present in each of the intermediate conductive layers 45 and the symmetry present in each of the stacking units 50, each of the intermediate conductive layers 45 may be formed into a one-dimensional periodic crystal lattice, which is beneficial for improving electron mobility. In other words, the conductivity of the intermediate conductive layers 45 may be significantly improved.

Referring back to FIG. 1, in some embodiments, the second semiconductor device 40 may further include two barrier layers 46 each being formed between one of the conductive contacts 42 and a corresponding one of the intermediate conductive layers 45. Each of the barrier layers 46 is provided for preventing metal atoms in the corresponding conductive contact 42 from diffusing through the corresponding intermediate conductive layer 45 into the IMD portion 31 of the interconnect layer Mₓ, so that undesired current leakage may be eliminated. In some embodiments, each of the barrier layers 46 may include titanium nitride (TiN), tungsten carbon nitride (WCN), tungsten nitride (WN), tantalum nitride (TaN), etc. Other materials suitable for forming the barrier layers 46 are also within the contemplated scope of the present disclosure. In some embodiments, each of the barrier layers 46 may have a thickness ranging from about 0.5 Å to about 50 nm.

In some embodiments, when the second semiconductor device 40 is configured as a 1T FeRAM, where the gate dielectric layer 43 is made of a ferroelectric material such as HZO, the second semiconductor device 40 may further includes a first interface layer 47 formed between the gate dielectric layer 43 and the gate electrode 44, and a second interface layer 48 formed between the gate dielectric layer 43 and the channel 41. Each of the interface layers 47, 48 is made of a high-k dielectric material. When a working voltage is applied to the second semiconductor device 40 through the gate electrode 44 and the conductive contacts 42, an electric field generated between the gate dielectric layer 43 and the gate electrode 44 may be reduced by the first interface layer 47, and an electric field generated between the gate dielectric layer 43 and the channel 41 may be reduced by the second interface layer 48. Thus, the endurance of the 1T FeRAM may be improved. In some embodiments, the first interface layer 47 may include titanium oxide, indium oxide, tantalum oxide, or combinations thereof. In some embodiments, the second interface layer 48 may include titanium oxide, indium oxide, or a combination thereof. In some embodiments, each of the interface layers 47, 48 may have a thickness ranging from about 0.5 Å to about 100 nm.

In some embodiments, the semiconductor device 40 further includes a capping layer 49 disposed on the channel 41, and the capping layer 49 and the channel 41 may be together referred to as a bi-layered channel structure. In some embodiments, the capping layer 49 includes indium gallium zinc oxide (IGZO). It is noted that a donor density in the capping layer 49 is lower than a donor density in the channel layer 41, and hence electrons may be tend to move within the channel layer 41, rather than within the capping layer 49.

In some alternative embodiments, the semiconductor structure 1 may further include additional features, and/or some features present in the semiconductor structure 1 may be modified, replaced, or eliminated without departure from the spirit and scope of the present disclosure.

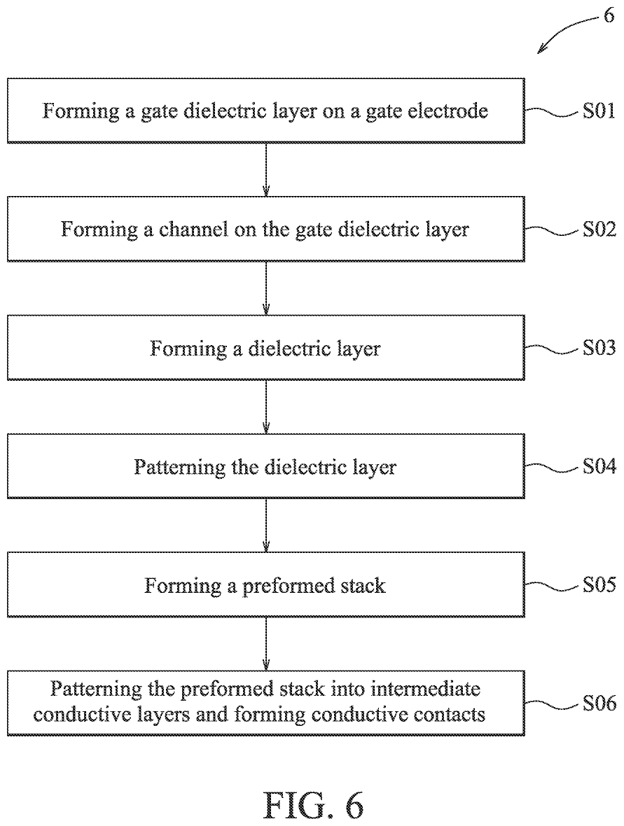

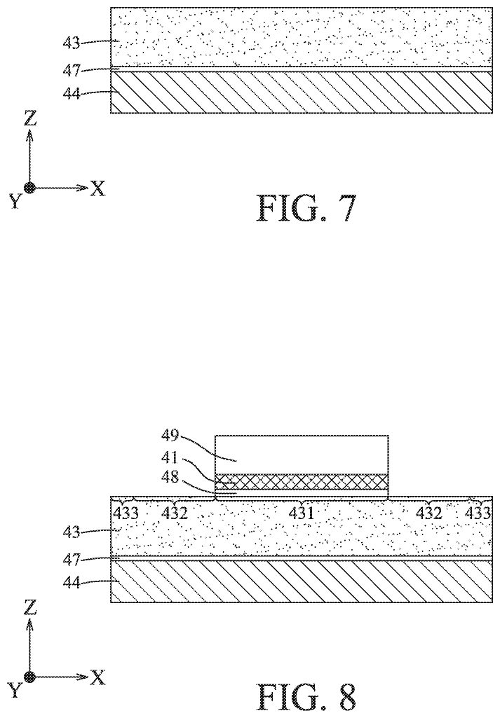

FIG. 6 is a flow diagram illustrating a method 6 for manufacturing a semiconductor structure 2 (see FIG. 12) in accordance with some embodiments. The semiconductor structure 2 is a portion of the semiconductor structure 1 shown in FIG. 1, and includes the interconnect layer Mₓ and the second semiconductor device 40 formed in the interconnect layer Mₓ. The method 6 may include steps S01 to S06. FIGS. 7 to 12 illustrate schematic views of intermediate stages of the method 6 in accordance with some embodiments. Similar numerals from the above-mentioned embodiments have been used where appropriate, with some construction differences being indicated with different numerals. In some other embodiments, the method 6 may be used for manufacturing a plurality of the second semiconductor devices 40 simultaneously, and the number of the second semiconductor devices 40 may vary according to practical requirements.

Referring to FIG. 6 and the example illustrated in FIG. 7, the method 6 begins at step S01, where the gate dielectric layer 43 is formed on the gate electrode 44 by atomic layer deposition (ALD), physical vapor deposition (PVD), chemical vapor deposition process (CVD), or other suitable deposition techniques. In some embodiments, prior to forming the gate dielectric layer 43, the first interface layer 47 is formed on the gate electrode 44 using ALD, PVD, CVD or other suitable techniques. In some embodiments, a patterning process, which may be a photolithography process, may be performed so that each of the first interface layer 47 and the gate dielectric layer 43 may have a desired dimension in an X direction or in a Y direction that is transverse to the X direction.

Referring to FIG. 6 and the example illustrated in FIG. 8, the method 6 proceeds to step S02, where the channel 41 is formed on the first region 431 of the gate dielectric layer 43 by a suitable deposition process (such as the examples described in step S01) and a patterning process which may be a photolithography process. In some embodiments, the second interface layer 48, the channel 41 and the capping layer 49 are sequentially formed on the first region 431 of the gate dielectric layer 43 by the above-mentioned processes. FIG. 8 is a schematic sectional view similar to that shown in FIG. 7, but illustrating the structure after step S02.

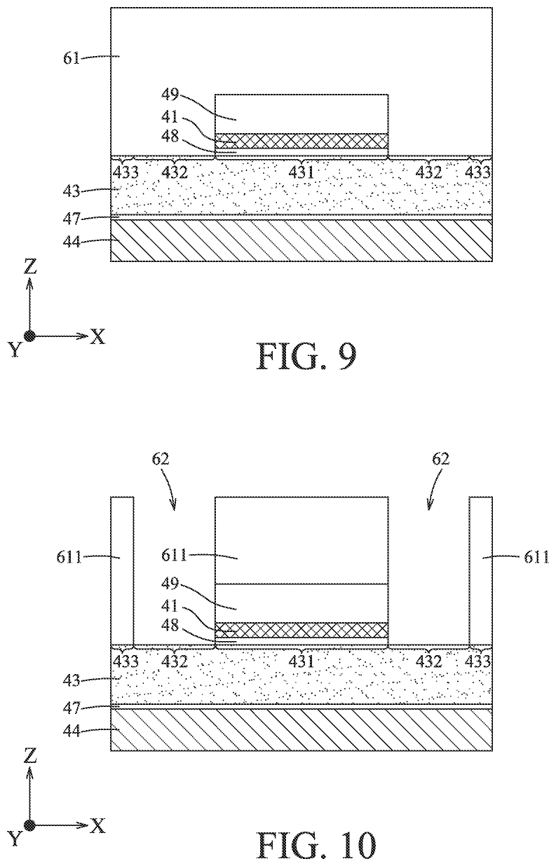

Referring to FIG. 6 and the example illustrated in FIG. 9, the method 6 proceeds to step S03, where a dielectric layer 61 for forming the IMD portion 31 of the interconnect layer Mₓ (see FIG. 1 or 12) is formed on the structure obtained after step S02 using a suitable deposition process (such as the examples described in step S01), followed by a planarization process, such as chemical mechanical polishing, to obtain a planar upper surface of the dielectric layer 61. FIG. 9 is a schematic sectional view similar to that shown in FIG. 8, but illustrating the structure after step S03.

As shown in FIG. 9, in some embodiments, the dielectric layer 61 is formed on a stack of the second interface layer 48, the channel 41 and the capping layer 49, and extends to cover the second and third regions 432, 433 of the gate dielectric layer 43 opposite to the gate electrode 44.

Referring to FIG. 6 and the example illustrated in FIG. 10, the method 6 proceeds to step S04, where the dielectric layer 61 (see FIG. 9) is patterned to have two openings 62 spaced apart from each other by, for example, a photolithography process, such that the two second regions 432 of the gate dielectric layer 43 are respectively exposed from the two openings 62. FIG. 10 is a schematic sectional view similar to that shown in FIG. 9, but illustrating the structure after step S04.

In some embodiments, as shown in FIG. 10, two opposite side surfaces of each of the second interface layer 48, the channel 41 and the capping layer 49 are also respectively exposed from the openings 62. After step S04, the patterned dielectric layer is denoted by the numeral 611.

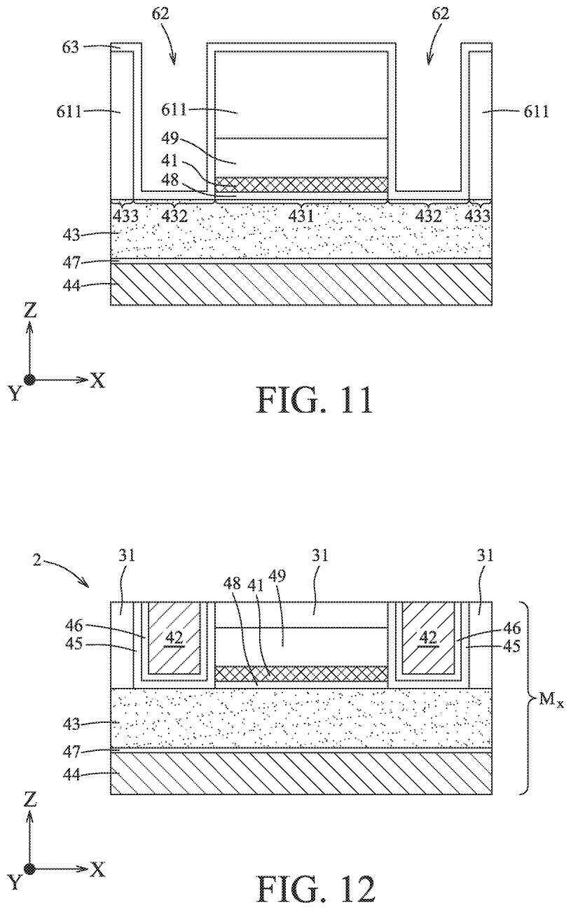

Referring to FIG. 6 and the example illustrated in FIG. 11, the method 6 proceeds to step S05, where a preformed stack 63 is formed on the structure obtained after step S04 by ALD or other suitable deposition process. FIG. 11 is a schematic sectional view similar to that shown in FIG. 10, but illustrating the structure after step S05. As shown in FIG. 11, the preformed stack 63 is formed along an inner surface of each of the openings 62 over the patterned dielectric layer 611.

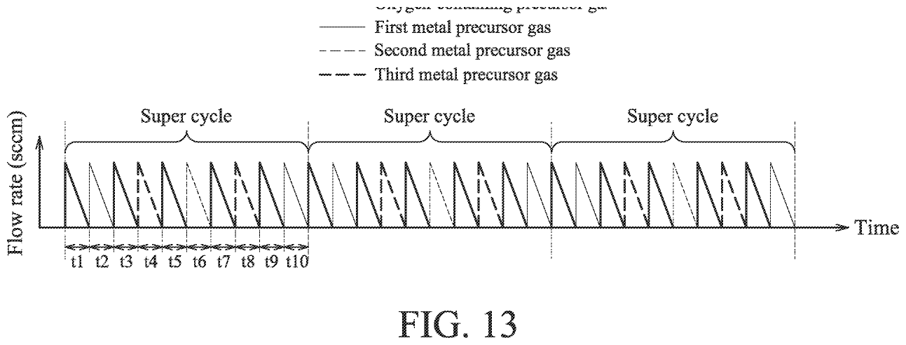

The preformed stack 63 will be formed into the two intermediate conductive layers 45 in a subsequent step, and thus the preformed stack 63 may have a configuration similar to that shown in FIGS. 2 to 5. In other words, the preformed stack 63 may have a number of the stacking unit(s) 50 that is the same as the number of the stacking unit(s) in each of the intermediate conductive layers 45 to be formed. For example, in order to obtain the intermediate conductive layers 45 exemplarily shown in FIG. 5, the preformed stack 63 includes three of the stacking units 50 each being exemplarily shown in FIG. 3. Precursor gases used for forming the preformed stack 63 includes an oxygen-containing precursor gas, a first metal precursor gas, a second metal precursor gas, and a third metal precursor gas. In some embodiments, the oxygen-containing precursor gas includes water vapor, oxygen gas, ozone gas, or combinations thereof. The first, second, or third metal precursor gas or a precursor for generating the same includes the first, second, or third metal atoms. It is noted that each of the first, second, and third metal atoms may be selected from indium (In), gallium (Ga), zinc (Zn), and tin (Sn). That is, the first, second, and third metal precursor gases may be each selected from an indium precursor gas, a gallium precursor gas, a zinc precursor gas and a tin precursor gas. In some embodiments, examples of the gallium precursor gas (and a precursor for generating the same) include triethylgallium ((CH₃CH₂)₃Ga), trimethylgallium (Ga(CH₃)₃), tris(dimethylamido)gallium(III) (C₁₂H₃₆Ga₂N₆), or combinations thereof. In some embodiments, examples of the indium precursor gas (and a precursor for generating the same) include indium(III) acetate (C₆H₉InO₆), indium(III) acetate hydrate (C₆H₉InO₆·xH₂O), indium(III) acetylacetonate (C₁₅H₂₁InO₆), or combinations thereof. In some embodiments, examples of the zinc precursor gas (and a precursor for generating the same) include bis(pentafluorophenyl) zinc ((C₆F₅)₂Zn), bis(2,2,6,6-tetramethyl-3,5-heptanedionato) zinc (II) (Zn(OCC(CH₃)₃CHCOC(CH₃)₃)₂), diethylzinc ((C₂H₅)₂Zn), diphenylzinc ((C₆H₅)₂Zn), zinc shot (Zn), or combinations thereof. In some embodiments, examples of the tin precursor gas (and a precursor for generating the same) include bis [bis(trimethylsilyl)amino]tin(II) ([[(CH₃)₃Si]₂N]₂Sn), tetraallyltin ((H₂C═CHCH₂)₄Sn), tetrakis(diethylamido)tin(IV) ([(C₂H₅)₂N]₄Sn), tetrakis(dimethylamido)tin(IV) ([(CH₃)₂N]₄Sn), tetramethyltin (Sn(CH₃)₄), tetravinyltin (Sn(CH═CH₂)₄), tin(II) acetylacetonate (C₁₀H₁₄O₄Sn), trimethyl(phenylethynyl)tin (C₆H₅C≡CSn(CH₃)₃), trimethyl(phenyl)tin (C₆H₅Sn(CH₃)₃), or combinations thereof. FIG. 13 is a graph illustrating a flow rate versus time for the oxygen-containing precursor gas, the first metal precursor gas, the second metal precursor gas, and the third metal precursor gas in accordance with some embodiments. The three super cycles shown in FIG. 13 are performed for forming the preformed stack 63 which has a configuration similar to that of the intermediate conductive layer 45 shown in FIG. 5. That is, each super cycle is performed for forming the stacking unit 50 shown in FIG. 3. Each of the super cycles sequentially includes pulsing the oxygen-containing precursor gas for a time period t1, pulsing the first metal precursor gas for a time period t2, pulsing the oxygen-containing precursor gas for a time period t3, pulsing the third metal precursor gas for a time period t4, pulsing the oxygen-containing precursor gas for a time period t5, pulsing the second metal precursor gas for a time period t6, pulsing the oxygen-containing precursor gas for a time period t7, pulsing the third metal precursor gas for a time period t8, pulsing the oxygen-containing precursor gas for a time period t9, and pulsing the first metal precursor gas for a time period t10.

The pulsing of the oxygen-containing precursor gas for the time period t1 aims to form sufficient-OH bonds on an exposed surface of the structure obtained in the previous step (e.g., forming-OH bonds on the inner surface of each of the openings 62), which may facilitate atomic deposition of the first metal atoms. Afterwards, during each of the time periods t2, t3, t4, t5, t6, t7, 18, 19, t10, at least one atomic layer of the first metal atoms, the second metal atoms, the third metal atoms, or the oxygen atoms is deposited on a previously formed atomic layer. Specifically, the first metal atoms deposited during the time period t2 may react with the oxygen atoms deposited during the time period t1, so as to form a first one of the two first metal oxide layers 51 of the corresponding stacking unit 50 (see FIG. 3 or 5). The third metal atoms deposited during the time period t4 may react with the oxygen atoms deposited during the time period t3, so as to form a first one of the two third metal oxide layers 53 of the corresponding stacking unit 50 (see FIG. 3 or 5) which is disposed on the first one of the first metal oxide layers 51. The second metal atoms deposited during the time period t6 may react with the oxygen atoms deposited during the time period t5, so as to form the second metal oxide layer 52 of the corresponding stacking unit 50 (see FIG. 3 or 5) which is disposed on the first one of the third metal oxide layers 53. The third metal atoms deposited during the time period t8 may react with the oxygen atoms deposited during the time period t7, so as to form a second one of the two third metal oxide layers 53 of the corresponding stacking unit 50 (see FIG. 3) which is disposed on the second metal oxide layer 52. The first metal atoms deposited during the time period t10 may react with the oxygen atoms during the time period t9, so as to form a second one of the two first metal oxide layers 51 of the corresponding stacking unit 50 (see FIG. 3) which is disposed on the second one of the third metal oxide layers 53.

In some embodiments, each of the time periods t1, t3, t5, t7, 19 is longer than about 1 second. In some other embodiments, each of the time periods t1, t3, t5, t7, t9 is longer than about 3 seconds and not longer than about 9 seconds. In some embodiments, each of the time periods t1, t2, t5, t7, t9 is longer than about 3 seconds and not longer than about 30 seconds. In some embodiments, each of the time periods t2, t4, 16, t8, t10 ranges from about 0.1 seconds to about 3 seconds. In some embodiments, the time period t1 may be controlled to be substantially equal to the time period t9, and the time period t2 may be controlled to be substantially equal to the time period t10, so as to obtain the two first metal oxide layers 51 (see FIG. 3) having the same thickness. In some embodiments, the time period t3 may be controlled to be substantially equal to the time period t7, and the time period t4 may be controlled to be substantially equal to the time period t8, so as to obtain the two third metal oxide layers 53 (see FIG. 3) having the same thickness. In some embodiments, each of the time periods t1, t3, t5, t7, t9 is longer than each of the time periods t2, t4, t6, t8, t10. In some embodiments, the time period t5 may be longer or shorter than or the same as each of the time periods t1, t3, t7, t9. In some embodiments, the time period t6 may be longer or shorter than or the same as each of the time periods t2, t4, t8, t10. In some embodiments, each of the oxygen-containing precursor gas, the first metal precursor gas, the second metal precursor gas, and the third metal precursor gas may be introduced in a flow rate ranging from about 100 sccm to about 10000 sccm. In some embodiments, the flow rate of each of the oxygen-containing precursor gas, the first metal precursor gas, the second metal precursor gas, and the third metal precursor gas may vary with time during the corresponding time period t1, t2, t3, t4, t5, 6, t7, 18, 19, or t10. For example, as shown in FIGS. 13 to 16, the flow rate of each of the oxygen-containing precursor gas, the first metal precursor gas, the second metal precursor gas, and the third metal precursor gas during the corresponding time period t1, t2, t3, t4, t5, t6, t7, t8, 9, or t10 may quickly reach a maximum value and then gradually and linearly decrease over time. Other flow rate profiles suitable for introducing the oxygen-containing precursor gas, the first metal precursor gas, the second metal precursor gas, or the third metal precursor gas are within the contemplated scope of the present disclosure.

It is worth noting that in each of the super cycles, the oxygen-containing precursor gas and a metal-containing precursor gas (e.g., the first metal precursor gas, the second metal precursor gas, or the third metal precursor gas) are alternately introduced into a reaction chamber used in step S05 for forming the preformed stack 63. Furthermore, each of the time periods t1, t3, t5, t7, 19 for pulsing the oxygen-containing precursor is relatively long. In view of the above, in the corresponding stacking unit 50, oxygen vacancies in each of the metal oxide layers 51, 52, 53 may be significantly reduced, and thus intermixing between two adjacent ones of the metal oxide layers 51, 52, 53 may be suppressed, thereby permitting formation of a multi-layered structure. In some embodiments, such manner for forming the preformed stack 63 as described above may be referred to as the oxygen-rich process.

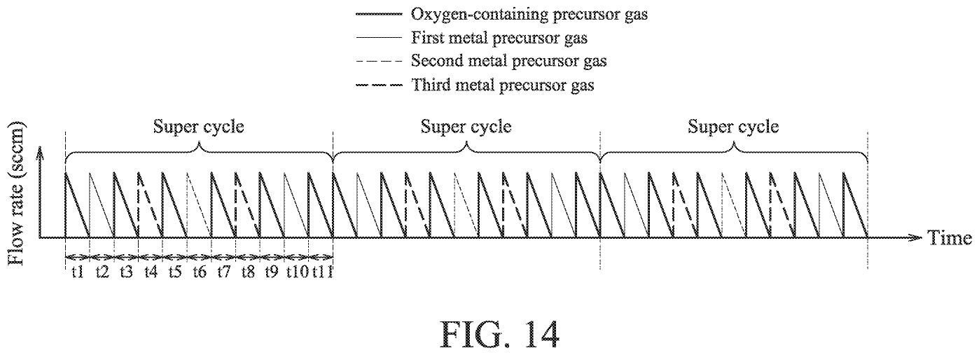

FIG. 14 is a graph illustrating a flow rate versus time for the oxygen-containing precursor gas, the first metal precursor gas, the second metal precursor gas, and the third metal precursor gas in accordance with some other embodiments. The super cycles shown in FIG. 14 are similar to those shown FIG. 13, but each of the super cycles shown in FIG. 14 further includes pulsing the oxygen-containing precursor gas for a time period t11 after pulsing the first metal precursor gas for the time period t10. The pulsing of the oxygen-containing precursor gas for the time period t11 is provided for further reducing oxygen vacancies in the corresponding stacking unit 50 (see FIG. 3 or 5). In some embodiments, the time period t11 is longer than about 1 second. In some other embodiments, the time period t11 is longer than about 3 seconds and not longer than about 9 seconds. In some embodiments, the time period t11 is longer than about 3 seconds and not longer than about 30 seconds. In some embodiments, the oxygen-containing precursor gas, which is pulsed for the time period t11, may be introduced in a flow rate ranging from about 100 sccm to about 10000 sccm. The oxygen-containing precursor gas, which is pulsed for the time period t11, may be introduced with the flow rate profile shown in FIG. 17, or other suitable flow rate profiles.

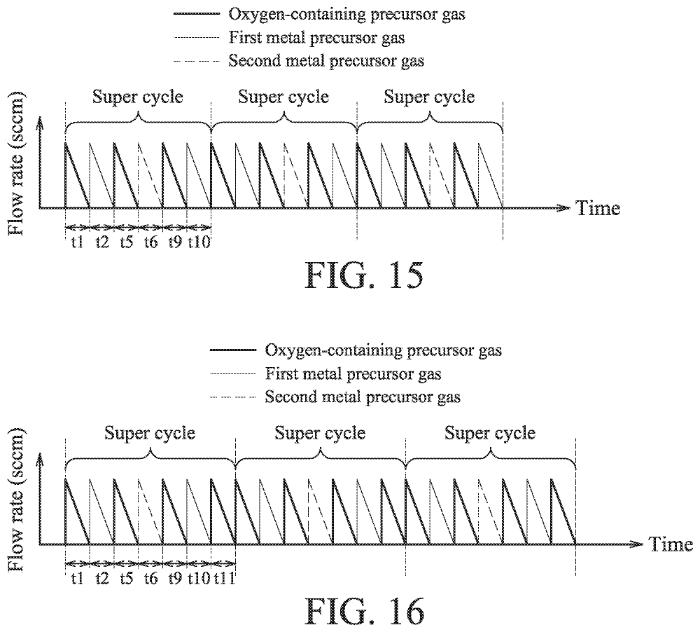

FIG. 15 is a graph illustrating a flow rate versus time for the oxygen-containing precursor gas, the first metal precursor gas, and the second metal precursor gas used for forming the preformed stack 63 which has a configuration similar to that of the intermediate conductive layer 45 shown in FIG. 4 in accordance with some embodiments. Each of the three super cycles shown in FIG. 15 is performed for forming the corresponding stacking unit 50 shown in FIG. 2. To wit, the third metal layers 53 shown in FIG. 3 or 5 are not formed and the third metal precursor gas is not introduced in each super cycle. As such, each of the super cycles for forming the corresponding stacking unit 50 (see FIG. 2 or 4) may be performed in a manner similar to that for forming the corresponding stacking unit 50 exemplarily shown in FIG. 3 or 5, but the pulsing of the oxygen-containing precursor gas for the time periods t3, t7 and the pulsing of the third metal precursor gas for the time periods t4, 18 as described above with reference to FIG. 13 are omitted. In other words, each of the super cycles in FIG. 15 sequentially includes pulsing the oxygen-containing precursor gas for the time period t1, pulsing the first metal precursor gas for the time period t2, pulsing the oxygen-containing precursor gas for the time period t5, pulsing the second metal precursor gas for the time period t6, pulsing the oxygen-containing precursor gas for the time period t9, and pulsing the first metal precursor gas for the time period t10. FIG. 16 is a graph illustrating a flow rate versus time for the oxygen-containing precursor gas, the first metal precursor gas, and the second metal precursor gas used for forming the preformed stack 63 which has a configuration similar to that shown in FIG. 4 in accordance with some other embodiments. As shown in FIG. 16, each of the super cycles sequentially includes pulsing the oxygen-containing precursor gas for the time period t1, pulsing the first metal precursor gas for the time period t2, pulsing the oxygen-containing precursor gas for the time period t5, pulsing the second metal precursor gas for the time period t6, pulsing the oxygen-containing precursor gas for the time period t9, pulsing the first metal precursor gas for the time period t10, and pulsing the oxygen-containing precursor gas for the time period t11.

Referring to FIG. 6 and the example illustrated in FIG. 12, the method 6 proceeds to step S06, where the two barrier layers 46 and the two conductive contacts 42 are formed, the preformed stack 63 (see FIG. 11) is formed into the two intermediate conductive layers 45, and the patterned dielectric layer 611 (see FIG. 11) is formed into the IMD portion 31 of the interconnect layer Mₓ, thereby obtaining the semiconductor structure 2. FIG. 12 is a schematic sectional view similar to that shown in FIG. 11, but illustrating the structure after step S06.

In some embodiments, step S06 may include (i) forming a first material layer (not shown) for forming the barrier layers 46 on the preformed stack 63 (see FIG. 11) by a suitable deposition process, (ii) forming a second material layer (not shown) for forming the conductive contacts 42 on the first material layer to fill the openings 62 (see FIG. 11) by a suitable deposition process, and (iii) performing a planarization process, such as chemical mechanical polishing, for a period of time until the dielectric layer 63 is exposed and the conductive contacts 42 have a predetermined height. Accordingly, the preformed stack 63 (see FIG. 11) is formed into the two intermediate conductive layers 45, the first material layer is formed into the two barrier layers 46, the second material layer is formed into the two conductive contacts 42, and the patterned dielectric layer 611 (see FIG. 11) is formed into the IMD portion 31 of the interconnect layer Mₓ.

In some embodiments, some steps in the method 6 may be modified, replaced, or eliminated without departure from the spirit and scope of the present disclosure.

In summary, the intermediate conductive layers 45, each of which is formed between the channel 41 and a respective one of the conductive contacts 42, may prevent an insulating interfacial metal oxide from being formed between the channel 41 and the respective conductive contact 42, thereby allowing an ohmic contact to be formed between the channel 41 and each of the intermediate conductive layers 45. In addition, since the intermediate conductive layers 45 are formed by the oxygen-rich process described in the method of present disclosure, formation of an interfacial metal oxide between one of the intermediate conductive layers 45 and a corresponding one of the conductive contacts 42 may be suppressed. Besides, layer-to-layer intermixing in each of the intermediate conductive layers 45 may be also suppressed, and thus the intermediate conductive layers 45 have a one-dimensional periodic crystal lattice and an improved conductivity. When the second semiconductor device 2 including the intermediate conductive layers 45 of the present disclosure is configured as a FeFET memory, the FeFET memory may have a relatively high drain current (Id) in a first polarization state (e.g., an initial state before programming) and a relatively high drain current (Id_PRG) in a second polarization state (e.g., a state after programming). Furthermore, the FeFET memory may also have a relatively low subthreshold swing value (i.e., the reciprocal of the subthreshold slope), a relatively faster transition between the first and second polarization states, and the device durability of the FeFET memory is not adversely affected by the formation of the intermediate conductive layers 45 of the present disclosure.

In accordance with some embodiments of the present disclosure, a method for manufacturing a semiconductor device includes: forming a channel including a semiconductor material; forming two intermediate conductive layers in contact with the channel, the two intermediate conductive layers being spaced apart from each other; and forming two conductive contacts respectively on the two intermediate conductive layers. Each of the two intermediate conductive layers includes at least one stacking unit. The at least one stacking unit includes two first metal oxide layers spaced apart from each other and a second metal oxide layer disposed between the two first metal oxide layers and extending along a lengthwise line such that the two first metal oxide layers are opposite to each other relative to the lengthwise line. Each of the two first metal oxide layers includes first metal atoms, and the second metal oxide layer includes second metal atoms that are different from the first metal atoms.

In accordance with some embodiments of the present disclosure, the at least one stacking unit includes multiple stacking units stacked on each other. Each of the two intermediate conductive layers has a first surface and a second surface opposite to the first surface, and extends along a reference plane which is equally spaced apart from the first surface and the second surface. The multiple stacking units are arranged such that at least a portion of each of the two intermediate conductive layers is divided by the reference plane into two halves which are mirror symmetric to each other.

In accordance with some embodiments of the present disclosure, a donor density in each of the two first metal oxide layers is greater than a donor density in the second metal oxide layer.

In accordance with some embodiments of the present disclosure, formation of the at least one stacking unit sequentially includes pulsing an oxygen-containing precursor gas for a first time period, pulsing a first metal precursor gas containing the first metal atoms for a second time period, pulsing the oxygen-containing precursor gas for a third time period, pulsing a second metal precursor gas containing the second metal atoms for a fourth time period, pulsing the oxygen-containing precursor gas for a fifth time period, and pulsing the first metal precursor gas for a sixth time period.

In accordance with some embodiments of the present disclosure, formation of the at least one stacking unit further includes, after pulsing the first metal precursor gas for the sixth time period, pulsing the oxygen-containing precursor gas for a seventh time period.

In accordance with some embodiments of the present disclosure, each of the first time period, the third time period, the fifth time period, and the seventh time period is longer than three seconds.

In accordance with some embodiments of the present disclosure, each of the first time period, the third time period, the fifth time period, and the seventh time period is longer than each of the second time period, the fourth time period and the sixth time period.

In accordance with some embodiments of the present disclosure, the two first metal oxide layers are symmetric with each other relative to the lengthwise line. The at least one stacking unit further includes two third metal oxide layers, each of which is formed between the second metal oxide layer and a respective one of the two first metal oxide layers such that the two third metal oxide layers are symmetric with each other relative to the lengthwise line. Each of the two third metal oxide layers includes third metal atoms that are different from the first metal atoms and the second metal atoms.

In accordance with some embodiments of the present disclosure, a donor density in each of the two third metal oxide layers is greater than a donor density in the second metal oxide layer.

In accordance with some embodiments of the present disclosure, each of the first, second and third metal atoms may be selected from indium (In), gallium (Ga), zinc (Zn), and tin (Sn).

In accordance with some embodiments of the present disclosure, a method for manufacturing a semiconductor structure includes: forming a ferroelectric layer on a gate electrode; forming a channel on the ferroelectric layer opposite to the gate electrode, the channel including a semiconductor material; forming two intermediate conductive layers in contact with the channel, the two intermediate conductive layers being spaced apart from each other; and forming two conductive contacts respectively on the two intermediate conductive layers such that each of the conductive contacts are separated from the channel by a respective one of the two intermediate conductive layers. Each of the two intermediate conductive layers includes at least one stacking unit. The at least one stacking unit includes two first metal oxide layers spaced apart from each other, and a second metal oxide layer disposed between the two first metal oxide layers and extending along a lengthwise line such that the two first metal oxide layers are opposite to each other relative to the lengthwise line. Each of the two first metal oxide layers includes first metal atoms, and the second metal oxide layer includes second metal atoms that are different from the first metal atoms.

In accordance with some embodiments of the present disclosure, each of the two first metal oxide layers is in contact with the second metal oxide layer.

In accordance with some embodiments of the present disclosure, the method further includes: forming a first interface layer between the gate electrode and the ferroelectric layer; and forming a second interface layer between the channel and the ferroelectric layer. Each of the first interface layer and the second interface layer includes a high dielectric constant material.

In accordance with some embodiments of the present disclosure, the channel is formed on a first region of the ferroelectric layer, and the two intermediate conductive layers are further formed to be in contact with two second regions of the ferroelectric layer, respectively. The first region is located between the two second regions.

In accordance with some embodiments of the present disclosure, a semiconductor device includes: a channel including a semiconductor material; two conductive contacts disposed on the channel and spaced apart from each other; two intermediate conductive layers, each of which is disposed between the channel and a respective one of the two conductive contacts, each of the two intermediate conductive layers including at least one stacking unit, the at least one stacking unit including two first metal oxide layers spaced apart from each other and a second metal oxide layer disposed between the two first metal oxide layers and extending along a lengthwise line such that the two first metal oxide layers are opposite to each other relative to the lengthwise line, each of the two first metal oxide layers including first metal atoms, the second metal oxide layer including second metal atoms that are different from the first metal atoms; a gate dielectric layer disposed on the channel; and a gate electrode disposed on the gate dielectric layer such that the gate electrode is separated from the channel through the gate dielectric layer, the gate electrode being spaced apart from each of the two conductive contacts.

In accordance with some embodiments of the present disclosure, the at least one stacking unit includes multiple stacking units stacked on each other. Each of the two intermediate conductive layers has a first surface and a second surface, and extends along a reference plane which is equally spaced apart from the first surface and the second surface. The multiple stacking units are arranged such that at least a portion of each of the two intermediate conductive layers is divided by the reference plane into two halves which are mirror symmetric to each other.

In accordance with some embodiments of the present disclosure, a donor density in each of the two first metal oxide layers is greater than a donor density in the second metal oxide layer.

In accordance with some embodiments of the present disclosure, the two first metal oxide layers are symmetric with each other relative to the lengthwise line. The at least one stacking unit further includes two third metal oxide layers, each of which is formed between the second metal oxide layer and a respective one of the two first metal oxide layers such that the two third metal oxide layers are symmetric with each other relative to the lengthwise line. Each of the two third metal oxide layers includes third metal atoms that are different from the first metal atoms and the second metal atoms.

In accordance with some embodiments of the present disclosure, a donor density in each of the two third metal oxide layers is greater than a donor density in the second metal oxide layer.

In accordance with some embodiments of the present disclosure, each of the first, second and third metal atoms may be selected from indium, gallium (Ga), zinc (Zn), and tin (Sn).

In accordance with some embodiments of the present disclosure, a method for manufacturing a semiconductor structure includes: forming a channel including a first semiconductor material; forming two intermediate conductive layers in contact with the channel, the two intermediate conductive layers being spaced apart from each other; forming two conductive contacts respectively on the two intermediate conductive layers such that each of the conductive contacts are separated from the channel by a respective one of the two intermediate conductive layers; forming a gate dielectric layer on the channel; and forming a gate electrode on the gate dielectric layer such that the gate electrode is separated from the channel by the gate dielectric layer. Each of the two intermediate conductive layers includes at least one stacking unit. The at least one stacking unit includes two first metal oxide layers spaced apart from each other and a second metal oxide layer disposed between the two first metal oxide layers and extending along a lengthwise line such that the two first metal oxide layers are opposite to each other relative to the lengthwise line. Each of the two first metal oxide layers includes first metal atoms, and the second metal oxide layer includes second metal atoms that are different from the first metal atoms.

In accordance with some embodiments of the present disclosure, the method further includes forming two barrier layers, each of which is formed between one of the two conductive contacts and a respective one of the two intermediate conductive layers.

In accordance with some embodiments of the present disclosure, each of the barrier layers includes a metal nitride.

In accordance with some embodiments of the present disclosure, the method further includes forming a capping layer on the channel layer opposite to the gate dielectric layer. The capping layer includes a second semiconductor material.

In accordance with some embodiments of the present disclosure, the first semiconductor material has a donor density that is greater than a donor density of the second semiconductor material.

In accordance with some embodiments of the present disclosure, the gate dielectric layer is disposed to separate the gate electrode from each of the two conductive contacts.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a channel including a semiconductor material;
forming two intermediate conductive layers in contact with the channel and spaced apart from each other, each of the two intermediate conductive layers including at least one stacking unit, the at least one stacking unit including
two first metal oxide layers spaced apart from each other, each of the two first metal oxide layers including first metal atoms, and
a second metal oxide layer disposed between the two first metal oxide layers and extending along a lengthwise line such that the two first metal oxide layers are opposite to each other relative to the lengthwise line, the second metal oxide layer including second metal atoms that are different from the first metal atoms; and
forming two conductive contacts respectively on the two intermediate conductive layers.

2. The method as claimed in claim 1, wherein the at least one stacking unit includes multiple stacking units stacked on each other, each of the two intermediate conductive layers having a first surface and a second surface opposite to the first surface, and extending along a reference plane which is equally spaced apart from the first surface and the second surface, the multiple stacking units being arranged such that at least a portion of each of the two intermediate conductive layers is divided by the reference plane into two halves which are mirror symmetric to each other.

3. The method as claimed in claim 1, wherein a donor density in each of the two first metal oxide layers is greater than a donor density in the second metal oxide layer.

4. The method as claimed in claim 1, wherein formation of the at least one stacking unit sequentially includes
pulsing an oxygen-containing precursor gas for a first time period,
pulsing a first metal precursor gas containing the first metal atoms for a second time period,
pulsing the oxygen-containing precursor gas for a third time period,
pulsing a second metal precursor gas containing the second metal atoms for a fourth time period,
pulsing the oxygen-containing precursor gas for a fifth time period, and
pulsing the first metal precursor gas for a sixth time period.

5. The method as claimed in claim 4, wherein formation of the at least one stacking unit further includes, after pulsing the first metal precursor gas for the sixth time period, pulsing the oxygen-containing precursor gas for a seventh time period.

6. The method as claimed in claim 5, wherein each of the first time period, the third time period, the fifth time period, and the seventh time period is longer than three seconds.

7. The method as claimed in claim 5, wherein each of the first time period, the third time period, the fifth time period, and the seventh time period is longer than each of the second time period, the fourth time period and the sixth time period.

8. The method as claimed in claim 1, wherein
the two first metal oxide layers are symmetric with each other relative to the lengthwise line, and
the at least one stacking unit further includes two third metal oxide layers, each of which is formed between the second metal oxide layer and a respective one of the two first metal oxide layers such that the two third metal oxide layers are symmetric with each other relative to the lengthwise line, each of the two third metal oxide layers including third metal atoms that are different from the first metal atoms and the second metal atoms.

9. The method as claimed in claim 8, wherein a donor density in each of the two third metal oxide layers is greater than a donor density in the second metal oxide layer.

10. The method as claimed in claim 9, wherein each of the first, second and third metal atoms may be selected from indium, gallium, zinc, and tin.

11. A method for manufacturing a semiconductor structure, comprising:
forming a ferroelectric layer on a gate electrode;
forming a channel on the ferroelectric layer opposite to the gate electrode, the channel including a semiconductor material;
forming two intermediate conductive layers in contact with the channel, the two intermediate conductive layers being spaced apart from each other, each of the two intermediate conductive layers including at least one stacking unit, the at least one stacking unit including
two first metal oxide layers spaced apart from each other, each of the two first metal oxide layers including first metal atoms, and
a second metal oxide layer disposed between the two first metal oxide layers and extending along a lengthwise line such that the two first metal oxide layers are opposite to each other relative to the lengthwise line, the second metal oxide layer including second metal atoms that are different from the first metal atoms; and
forming two conductive contacts respectively on the two intermediate conductive layers such that each of the conductive contacts are separated from the channel by a respective one of the two intermediate conductive layers.

12. The method as claimed in claim 11, wherein each of the two first metal oxide layers is in contact with the second metal oxide layer.

13. The method as claimed in claim 11, further comprising:
forming a first interface layer between the gate electrode and the ferroelectric layer; and
forming a second interface layer between the channel and the ferroelectric layer, each of the first interface layer and the second interface layer including a high dielectric constant material.

14. The method as claimed in claim 11, wherein
the channel is formed on a first region of the ferroelectric layer, and
intermediate conductive layers are further formed to be in contact with two second regions of the ferroelectric layer, respectively, the first region being located between the two second regions.

15. A semiconductor device, comprising:
a channel including a semiconductor material;
two conductive contacts disposed on the channel and spaced apart from each other;
two intermediate conductive layers, each of which is disposed between the channel and a respective one of the two conductive contacts, each of the two intermediate conductive layers including at least one stacking unit, the at least one stacking unit including
two first metal oxide layers spaced apart from each other, each of the two first metal oxide layers including first metal atoms, and
a second metal oxide layer disposed between the two first metal oxide layers and extending along a lengthwise line such that the two first metal oxide layers are opposite to each other relative to the lengthwise line, the second metal oxide layer including second metal atoms that are different from the first metal atoms;
a gate dielectric layer disposed on the channel; and
a gate electrode disposed on the gate dielectric layer such that the gate electrode is separated from the channel through the gate dielectric layer, the gate electrode being spaced apart from each of the two conductive contacts.

16. The semiconductor device as claimed in claim 15, wherein the at least one stacking unit includes multiple stacking units stacked on each other, each of the two intermediate conductive layers having a first surface and a second surface, and extending along a reference plane which is equally spaced apart from the first surface and the second surface, the multiple stacking units being arranged such that at least a portion of each of the two intermediate conductive layers is divided by the reference plane into two halves which are mirror symmetric to each other.

17. The semiconductor device as claimed in claim 15, wherein a donor density in each of the two first metal oxide layers is greater than a donor density in the second metal oxide layer.

18. The semiconductor device as claimed in claim 15, wherein
the two first metal oxide layers are symmetric with each other relative to the lengthwise line, and
the at least one stacking unit further includes two third metal oxide layers, each of which is formed between the second metal oxide layer and a respective one of the two first metal oxide layers such that the two third metal oxide layers are symmetric with each other relative to the lengthwise line, each of the two third metal oxide layers including third metal atoms that are different from the first metal atoms and the second metal atoms.

19. The semiconductor device as claimed in claim 18, wherein a donor density in each of the two third metal oxide layers is greater than a donor density in the second metal oxide layer.

20. The semiconductor device as claimed in claim 18, wherein each of the first, second and third metal atoms may be selected from indium, gallium, zinc, and tin.
